(19) United States
(12) Patent Application Publication
(10) Pub. No.: US 2024/0413118 A1
(43) Pub. Date: Dec. 12, 2024

(54) SOLDER BARRIER STRUCTURE FOR POWER MODULES

(71) Applicant: Infineon Technologies AG, Neubiberg (DE)

(72) Inventors: Peter Scherl, Lappersdorf (DE); Adrian Lis, Regensburg (DE)

(21) Appl. No.: 18/332,858

(22) Filed: Jun. 12, 2023

(51) Int. Cl. H01L 23/00; H05K 1/02; H05K 1/18

(52) U.S. Cl. CPC H01L 24/32; H05K 1/0272; H05K 1/181; H01L 2224/26145; H05K 2201/10022; H05K 2201/10166; H05K 2201/2081

(57) ABSTRACT

A power module is disclosed herein. In one embodiment, the power modules includes a solder repellent structure that adjoins a metallic surface of a substrate outside a perimeter of an electronic component attached to the metallic surface of the substrate and positioned adjacent to one or more sides of the electronic component, the solder repellent structure being configured to repel molten solder. In another embodiment, the power modules includes a solder wetting structure that adjoins a metallic surface of a substrate outside a perimeter of an electronic component attached to the metallic surface of the substrate and positioned adjacent to one or more sides of the electronic component, where excess solder adheres to the solder wetting structure.

### BACKGROUND

Power modules typically include power semiconductor dies (chips) such as power MOSFET (metal-oxide-semiconductor field-effect transistor) dies, IGBT (insulated gate bipolar transistor) dies, JFET (junction field-effect transistor) dies, HEMT (high electron mobility transistor) dies, power diode dies, etc. and additional electronic components such as capacitors, resistors, etc. attached to one or more substrates. The electronic components are typically attached to the substrate(s) using solder.

During the component attach process, the solder becomes molten. Excess molten solder that squeezes out from under one electronic component can wet to an adjacent electronic component, forming a solder bridges that can cause shorting or other electrical problems. For example, excess molten solder that squeezes out from under a power semiconductor die can wet to a shunt resistor attached to the same substrate and used for current sensing. Shunt resistors often include an alloy that has a low temperature coefficient (e.g., between 20 and 60° C.) and a wide temperature range (e.g., up to 140° C. or higher). If solder wets to the precision alloy part of a shunt resistor, a parallel current path is created and the electrical resistance of the shunt resistor can drop below a threshold which causes an electrical failure during testing.

Even if a minimum amount of solder is used for attaching an electronic component to a substrate, which risks non-ideal wetting of the component and may lead to solder voids under the component, the neighbouring structure (e.g., a shunt resistor) still attracts the solder which can result in solder bridging and electrical shorting.

Thus, there is a need for an improved technique which reduces solder bridging in power modules.

### SUMMARY

According to an embodiment of a power module, the power module comprises: a substrate having a metallic surface; an electronic component attached to the metallic surface of the substrate; and a solder repellent structure adjoining the metallic surface of the substrate outside a perimeter of the electronic component and positioned adjacent to one or more sides of the electronic component, wherein the solder repellent structure is configured to repel molten solder.

According to another embodiment of a power module, the power module comprises: a substrate having a metallic surface; a semiconductor die attached to the metallic surface of the substrate; a shunt resistor attached to the metallic surface of the substrate; and a solder repellent structure adjoining the metallic surface of the substrate and laterally interposed between the semiconductor die and the shunt resistor, wherein the solder repellent structure is configured to repel molten solder.

According to another embodiment of a power module, the power module comprises a substrate having a metallic surface; a semiconductor die attached to the metallic surface of the substrate by a first solder joint; a shunt resistor attached to the metallic surface of the substrate; and a solder wetting structure adjoining the metallic surface of the substrate and laterally interposed between the semiconductor die and the shunt resistor, wherein excess solder squeezed out from under the semiconductor die adheres to the solder wetting structure.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a partial top perspective view of a power module, in the region of a barrier structure that prevents wetting of molten solder to a sensitive area of the power module.

FIG. 2 illustrates an embodiment of producing the barrier structure configured as a solder repellent structure.

FIG. 3 illustrates the same view of the power module as FIG. 1, but after soldering the electronic components of the power module to a metallic surface of a substrate.

FIG. 4 illustrates another embodiment of producing the barrier structure configured as a solder repellent structure.

FIG. 5 illustrates a partial top perspective view of the power module, according to another embodiment.

FIG. 6 illustrates a partial top perspective view of the power module, according to another embodiment.

### DETAILED DESCRIPTION

The embodiments described herein provide a structure that acts as a barrier against wetting of molten solder to a sensitive area of a power module. In some embodiments, the barrier structure is a solder repellent structure that is configured to repel molten solder away from a sensitive area of the power module. In other embodiments, the barrier structure is a solder wetting structure to which excess solder adheres instead of to a sensitive area of the power module. In each case, the barrier structure reduces solder bridging/shorting in power modules.

Described next, with reference to the figures, are exemplary embodiments of the barrier structure, power modules that include the barrier structure, and methods of producing the barrier structure.

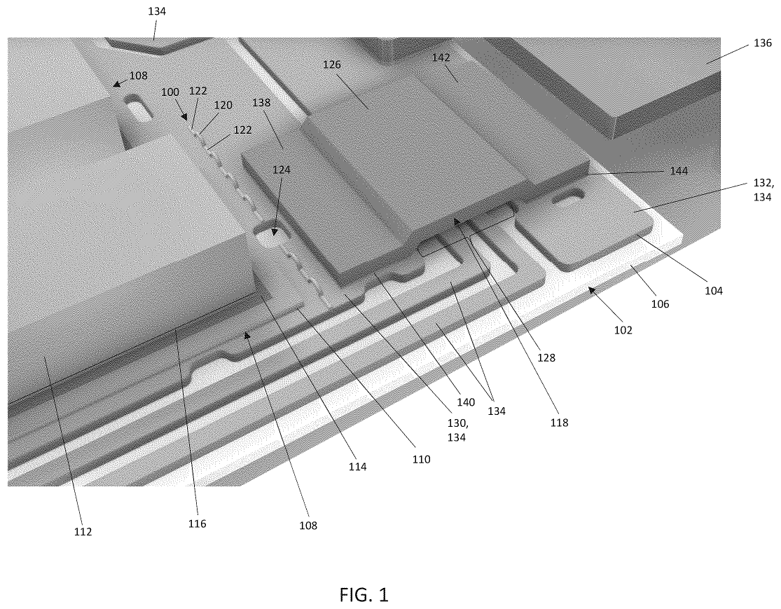

FIG. 1 illustrates a partial top perspective view of a power module, in the region of a barrier structure 100 that prevents wetting of molten solder to a sensitive area of the power module. A substrate 102 included in the power module has a metallic surface 104 to which the barrier structure 100 adjoins. The substrate 102 may be, e.g., a metallic substrate such as a Cu (copper) substrate like a die paddle of a Cu lead frame. The substrate 102 instead may be a direct bonded copper (DBC) substrate, an active metal brazed (AMB) substrate, an insulated metal substrate (IMS), etc., where the metallic surface 104 of the substrate 102 is a metalized surface of an electrically insulative body 106.

Electronic components are attached to the metallic surface 104 of the substrate 102. For example, semiconductor dies 108 may be attached to the metallic surface 104 of the substrate 102 by a respective solder joint 110. One or more of the semiconductor dies 108 may be a logic die such as a processor die, memory die, etc., a power semiconductor die such as a power transistor die, a power diode die, a half bridge die, etc., or a die that combines logic and power devices on the same semiconductor substrate. In one embodiment, at least some of the semiconductor dies 108 are vertical power semiconductor dies each having a primary current path between opposing main sides of the respective die 108. Examples of vertical power semiconductor dies include but are not limited to power Si MOSFETs, IGBTs, SiC MOSFETs, GaN HEMTs, power diodes, etc. A metallic spacer 112 such as a Cu (copper) block is shown attached to a contact pad 114 of each semiconductor die 108 by a solder joint 116 in FIG. 1. The spacers 112 may be omitted or replaced by a different structure such as a metallic clip frame, a metallic lead frame, etc.

Additional electronic components may be attached to the metallic surface 104 of the substrate 102. For example, one or more shunt resistors 118 may be attached to the metallic surface 104 of the substrate 106. A shunt resistor 118 is a resistor used to measure electric current, by measuring the voltage drop across the shunt resistor 118.

The barrier structure 100 adjoins the metallic surface 104 of the substrate 102 outside a perimeter of each electronic component 108, 118 and is positioned adjacent to one or more sides of a neighboring electronic component 108, 118. For example, in FIG. 1, the barrier structure 100 is laterally interposed between a semiconductor die 108 and a shunt resistor 118.

In one embodiment, the barrier structure 100 is a solder repellent structure configured to repel molten (liquefied) solder such that excess solder squeezed out from under the neighboring semiconductor die 108 does not adhere to the barrier structure 100, thereby repelling molten solder away from the neighboring shunt resistor 118. In another embodiment, the barrier structure 100 is a solder wetting structure that attracts excess solder squeezed out from under the semiconductor die 108 such that the excess solder adheres to the barrier structure 100 instead of to the neighboring shunt resistor 118.

In FIG. 1, the barrier structure 100 is configured as a solder repellent structure. For example, the barrier structure 100 may comprise aluminum such as an aluminum wire. Aluminum has a very high affinity to oxygen. When a new aluminum surface is exposed in the presence of air or any other oxidizing agent, the aluminum quickly develops a thin, hard film of aluminum oxide. Molten solder will not adhere to aluminum oxide, making an aluminum-based barrier structure non-wettable. Lead-based or lead-free solder may be used to attach electronic components to the metallic surface 104 of the substrate 102. For example, a flux-free solder such as PbSnAg may be used to attach electronic components to the metallic surface 104 of the substrate 102. Solder wetting to aluminum is very challenging, even if the aluminum oxide layer is removed just prior to soldering. In the case of aluminum or another metal or metal alloy that is non-wettable, the barrier structure 100 may be in the form of one or more ribbons or round wires 120 attached to the metallic surface 104 of the substrate 102 by at least two different wedge stitch bonds 122, e.g., as shown in FIG. 1.

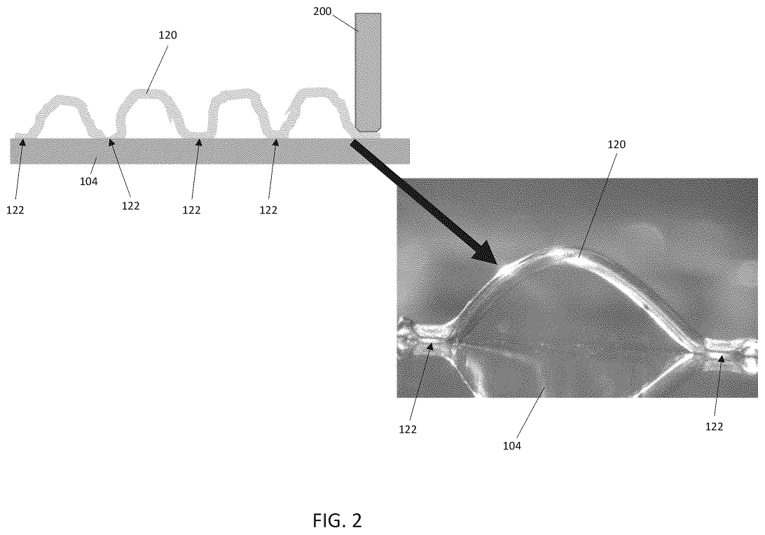

FIG. 2 illustrates an embodiment of producing the barrier structure 100 configured as a solder repellent structure. According to this embodiment, the barrier structure 100 is in the form of a ribbon or round wire structure. For example, the barrier structure 100 may be implemented as one or more ribbons or round wires 120 attached to the metallic surface 104 of the substrate 102 by at least two different wedge stitch bonds 122. A bonding capillary 200 forms a wedge stitch bond 122 by compressing (ultrasonically bonding) an area of the bond wire 120 and the underlying metallic surface 104 of the substrate 102. The bond wire 120 may have a diameter up to 1 mm, for example. FIG. 2 provides an enlarged view of one round wire 120, to emphasize the wedge stitch bonds 122 of the round wire 120. A ribbon may be used instead of a round wire.

As shown in FIG. 1, the barrier structure 100 may bridge a solder stop hole 124 formed in the metallic surface 104 of the substrate 102. Separately or in combination, the barrier structure 100 may include more than one row of ribbon or round wires 120 wedge stitch bonded to the metallic surface 104 of the substrate 102 between the semiconductor die 108 and the shunt resistor 118.

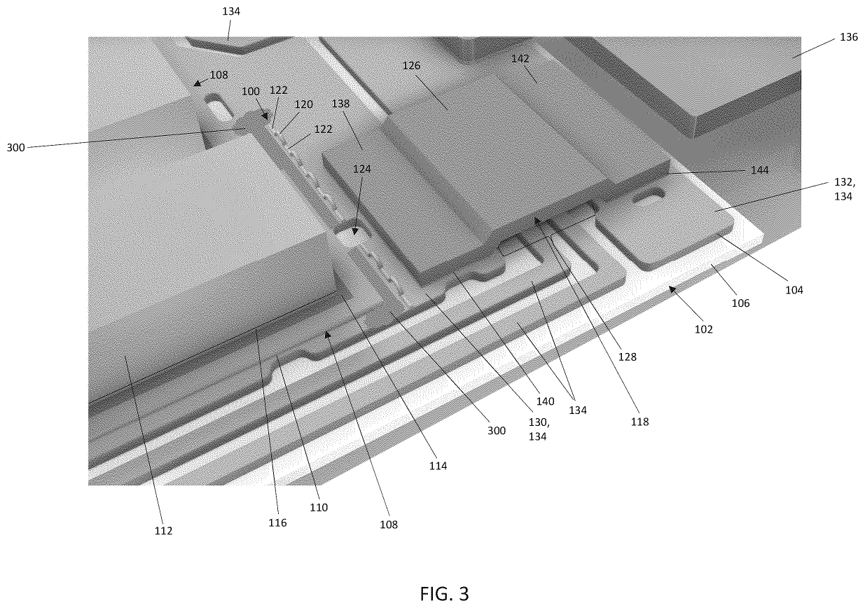

FIG. 3 illustrates the same view of the power module as FIG. 1, but after soldering the electronic components to the metallic surface 104 of the substrate 102. As shown in FIG. 3, excess solder 300 that melts and squeezes out from under the semiconductor die 108 during production of the power module is repelled by the barrier structure 100, preventing undesired solder bridging to the neighboring shunt resistor 118. In the case of flux-free solder, a relatively high processing/melting temperature (e.g., up to 360 C) is used compared to solders that contain flux. Such a direct high temperature attach process would normally exasperate solder bridging issues, except that the excess solder 300 that squeezes out from under the semiconductor die 108 in the direction of the neighboring shunt resistor 118 during the solder reflow process is repelled by the barrier structure 100 which prevents solder bridging to the shunt resistor 118.

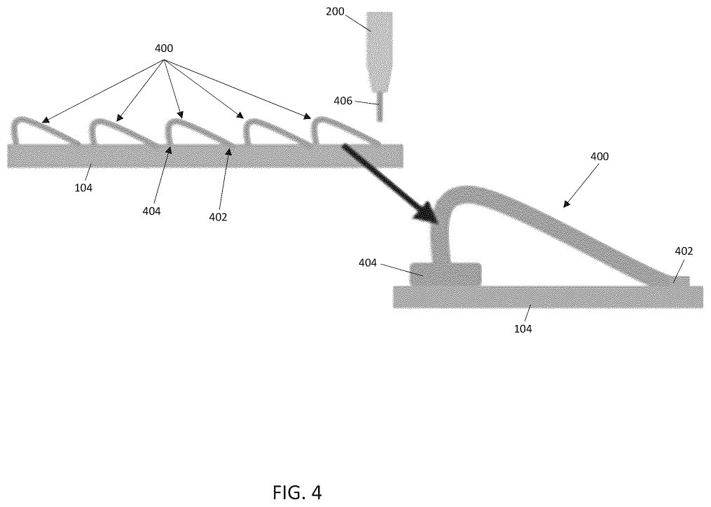

FIG. 4 illustrates another embodiment of producing the barrier structure 100 configured as a solder repellent structure. According to this embodiment, the barrier structure 100 is implemented as separate bond wire loops 400. Each separate bond wire loop 400 has both a tail end 402 and a ball end 404 attached to the metallic surface 104 of the substrate 102. A bonding capillary 200 forms the ball end 404 by melting the end of a bond wire 406 to form a free-air ball, placing the free-air ball into contact with the metallic surface 104 of the substrate 102, and applying heat and ultrasonic forces to the free-air ball to form a metallurgical weld between the ball and the metallic surface 104 of the substrate 102 while also allowing deformation of the ball bond into the final shape of the ball end 404. The bonding capillary 200 then runs the bond wire 406 a defined length, forms a second free-air ball at the end of the bond wire 406, and applies pressure and ultrasonic forces such that the second ball is crushed on the metallic surface 104 of the substrate 102 to form the tail end 402 which is in the form a stitch bond in FIG. 4. Above the substrate surface, the separate bond wire loops 400 may have a low height and be mostly flat between the respective loop ends 402, 404.

FIG. 4 also provides an enlarged view of one bond wire loop 400, to emphasize the tail and ball ends 402, 404 of the bond wire loop 400. The barrier structure 100 may include more than one row of separate bond wire loops 400 attached to the metallic surface 104 of the substrate 102 between the semiconductor die 108 and the shunt resistor 118. Similar to what is shown in FIG. 3, excess solder 300 that melts and squeezes out from under the semiconductor die 108 during production of the power module is repelled by each row of separate bond wire loops 400, preventing undesired solder bridging to the neighboring shunt resistor 118.

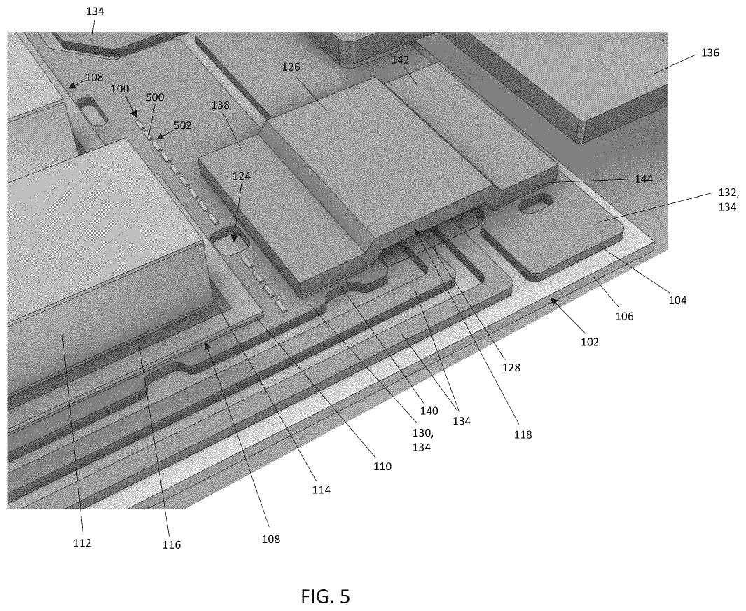

FIG. 5 illustrates a partial top perspective view of the power module, according to another embodiment. In FIG. 5, the barrier structure 100 is configured as a solder repellent structure that comprises wire wedges 500 attached to the metallic surface 104 of the substrate 102. The wire wedges 500 are laterally spaced apart from one another by a gap 502. The wire wedges 500 may be realized by wedge bonding a bond wire or ribbon to the metallic surface 104 of the substrate 102 and breaking off the bond wire/ribbon at the wedge bond joint. The barrier structure 100 may include more than one row of spaced apart wire wedges 500 attached to the metallic surface 104 of the substrate 102 between the semiconductor die 108 and the shunt resistor 118. Similar to what is shown in FIG. 3, excess solder 300 that melts and squeezes out from under the semiconductor die 108 during production of the power module is repelled by each row of spaced apart wire wedges 500, preventing undesired solder bridging to the neighboring shunt resistor 118.

For embodiments in which the barrier structure 100 is configured to repel solder and comprises a metal or metal alloy, the barrier structure 100 may be ball bonded, wedge bonded, ribbon bonded, or a combination of ball bonded, wedge bonded and/or ribbon bonded to the metallic surface 104 of the substrate 102.

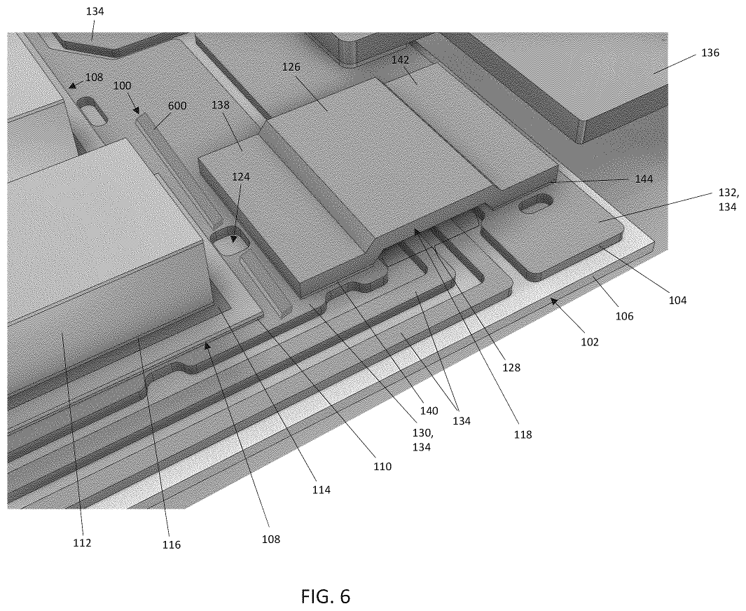

FIG. 6 illustrates a partial top perspective view of the power module, according to another embodiment. In FIG. 6, the barrier structure 100 is configured as a solder repellent structure that comprises a polymer 600 configured to repel molten solder such as a plastic, photoresist, etc. applied to the metallic surface 104 of the substrate 102. The manner by which the polymer 600 is applied to the metallic surface 104 of the substrate 102 depends on the type of polymer 600 used. For example, the polymer 600 may be deposited, screen printed, etc. on the metallic surface 104 of the substrate 102.

The barrier structure 100 shown in FIGS. 1, 3, 5 and 6 instead may be a solder wetting structure configured to attract excess that solder squeezes out from under a semiconductor die 108 such that the excess solder adheres to the barrier structure 100 instead of to a neighboring shunt resistor 118. For example, the barrier structure 100 may comprise one or more rows of copper ribbons or round wires 120 as shown in FIGS. 1 through 3, or one or more rows of separate copper bond wire loops 400 as shown in FIG. 4, or one or more rows of laterally spaced apart copper wire wedges 500 as shown in FIG. 5. However, other metals or metal alloys to which solder readily wets may be used as the barrier structure 100 such as but not limited to Ag (silver), Au (gold), Pt (platinum), etc. In each case, the barrier structure 100 reduces solder bridging/shorting in power modules, e.g., to a shunt resistor 118.

As shown in FIGS. 1, 3, 5, and 6, the shunt resistor 118 may include a first section 126 spaced apart from the metallic surface 104 of the substrate 102 in a vertical direction that is perpendicular to the metallic surface 104 of the substrate 102. The first section 126 of the shunt resistor 118 at least partially spans a gap 128 between a first part (island) 130 and a second part (island) 132 of the metallic surface 104 of the substrate 102. In the case of the substrate 102 being a DBC substrate, an AMB substrate, or an IMS, the metallic surface 104 of the substrate 102 may be patterned by etching, stamping, etc. to define metallic islands including the first and second parts 130, 132 of the metallic surface 104. The electronic components 108, 118 included in the power module are attached to some of the islands 134. Metallic connections 136 such as metallic leads, metallic clips, metallic pins, etc. are also attached to some of the islands 134, to provide electrical connections to the power module and route the electrical connections along the substrate 102.

The shunt resistor 118 may further include a second section 138 extending from a first end of the first section 126 and attached to the first part 130 of the metallic surface 104 of the substrate 102 by a solder joint 140. A third section 142 of the shunt resistor 118 may extend from a second end of the first section 126 opposite the first end and be attached to the second part 132 of the metallic surface 104 of the substrate 102 by a solder joint 144.

The first section 126 of the shunt resistor 118 may comprise zeranin which is an alloy comprising Cu, Mn (Manganese), and Zn (Zinc), typically 7% Mn, 2.3% Sn, and 90.7% Cu by mass. Zeranin has a low temperature coefficient (e.g., between 20 and 60° C.) and a wide temperature range (e.g., up to 140° C. or higher), making zeranin useful as a precision resistor. However, the effectiveness of zeranin as a precision resistor is impeded by solder wetting to the first section 126 of the shunt resistor 118 which comprises zeranin.

In one embodiment, the semiconductor die 108 neighboring the shunt resistor 118 is attached to the first part 130 of the metallic surface 104 of the substrate 102 and the barrier (solder repellent or solder wetting) structure 100 prevents solder wetting of the first section 126 of the shunt resistor 118. Consequently, the barrier structure 100 prevents excess solder 130 that squeezes out from under the neighboring semiconductor die 108 from forming a parallel current path with the shunt resistor 118. The barrier structure 100 does this by either repelling the excess molten solder 130 away from the shunt resistor 118 or by permitting the excess molten solder 130 to adhere to the barrier structure 100 instead of the shunt resistor 118.

Although the present disclosure is not so limited, the following numbered examples demonstrate one or more aspects of the disclosure.

Example 1. A power module, comprising: a substrate having a metallic surface; an electronic component attached to the metallic surface of the substrate; and a solder repellent structure adjoining the metallic surface of the substrate outside a perimeter of the electronic component and positioned adjacent to one or more sides of the electronic component, wherein the solder repellent structure is configured to repel molten solder.

Example 2. The power module of example 1, wherein the solder repellent structure comprises aluminum.

Example 3. The power module of example 1, wherein the solder repellent structure comprises a polymer.

Example 4. The power module of example or 2, wherein the solder repellent structure comprises a plurality of separate bond wire loops, and wherein each separate bond wire loop has both a tail end and a ball end attached to the metallic surface of the substrate.

Example 5. The power module of example 1 or 2, wherein the solder repellent structure comprises one or more ribbons or round wires attached to the metallic surface of the substrate by at least two different wedge stitch bonds.

Example 6. The power module of example 1 or 2, wherein the solder repellent structure comprises a plurality of wire wedges attached to the metallic surface of the substrate and laterally spaced apart from one another.

Example 7. The power module of any of examples 1 through 6, wherein the substrate is a direct bonded copper (DBC) substrate, and wherein the metallic surface of the substrate is a metalized surface of an electrically insulative body of the DBC substrate.

Example 8. The power module of any of examples 1 and 2 through 7, wherein the solder repellent structure is in the form of a wire or ribbon structure.

Example 9. The power module of any of examples 1 through 8, wherein the electronic component is a shunt resistor.

Example 10. The power module of example 9, further comprising: a semiconductor die attached to the metallic surface of the substrate by a solder joint, wherein the solder repellent structure is laterally interposed between the semiconductor die and the shunt resistor.

Example 11. The power module of example 9 or 10, wherein the shunt resistor comprises: a first section spaced apart from the metallic surface of the substrate in a vertical direction that is perpendicular to the metallic surface of the substrate, the first section at least partially spanning a gap between a first part and a second part of the metallic surface of the substrate; a second section extending from a first end of the first section and attached to the first part of the metallic surface of the substrate by a first solder joint; and a third section extending from a second end of the first section opposite the first end and attached to the second part of the metallic surface of the substrate by a second solder joint.

Example 12. The power module of example 11, wherein the first section of the shunt resistor comprises zeranin, and wherein the solder repellent structure is configured to prevent solder wetting of the first section of the shunt resistor.

Example 13. A power module, comprising: a substrate having a metallic surface; a semiconductor die attached to the metallic surface of the substrate; a shunt resistor attached to the metallic surface of the substrate; and a solder repellent structure adjoining the metallic surface of the substrate and laterally interposed between the semiconductor die and the shunt resistor, wherein the solder repellent structure is configured to repel molten solder.

Example 14. The power module of example 13, wherein the shunt resistor comprises: a first section spaced apart from the metallic surface of the substrate in a vertical direction that is perpendicular to the metallic surface of the substrate, the first section at least partially spanning a gap between a first part and a second part of the metallic surface of the substrate; a second section extending from a first end of the first section and attached to the first part of the metallic surface of the substrate by a first solder joint; and a third section extending from a second end of the first section opposite the first end and attached to the second part of the metallic surface of the substrate by a second solder joint.

Example 15. The power module of example 14, wherein the first section of the shunt resistor comprises zeranin, wherein the semiconductor die is attached to the first part of the metallic surface of the substrate, and wherein the solder repellent structure is configured to prevent solder wetting of the first section of the shunt resistor.

Example 16. The power module of any of examples 13 through 15, wherein the solder repellent structure is in the form of a wire or ribbon structure that comprises aluminum.

Example 17. A power module, comprising: a substrate having a metallic surface; a semiconductor die attached to the metallic surface of the substrate by a first solder joint; a shunt resistor attached to the metallic surface of the substrate; and a solder wetting structure adjoining the metallic surface of the substrate and laterally interposed between the semiconductor die and the shunt resistor, wherein excess solder squeezed out from under the semiconductor die adheres to the solder wetting structure.

Example 18. The power module of example 17, wherein the shunt resistor comprises: a first section spaced apart from the metallic surface of the substrate in a vertical direction that is perpendicular to the metallic surface of the substrate, the first section at least partially spanning a gap between a first part and a second part of the metallic surface of the substrate; a second section extending from a first end of the first section and attached to the first part of the metallic surface of the substrate by a second solder joint; and a third section extending from a second end of the first section opposite the first end and attached to the second part of the metallic surface of the substrate by a third solder joint.

Example 19. The power module of example 18, wherein the first section of the shunt resistor comprises zeranin, and wherein the semiconductor die is attached to the first part of the metallic surface of the substrate by the first solder joint.

Example 20. The power module of any of examples 17 through 19, wherein the solder repellent structure is in the form of a wire or ribbon structure that comprises aluminum.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power module, comprising:
a substrate having a metallic surface;
an electronic component attached to the metallic surface of the substrate; and
a solder repellent structure adjoining the metallic surface of the substrate outside a perimeter of the electronic component and positioned adjacent to one or more sides of the electronic component,
wherein the solder repellent structure is configured to repel molten solder.

2. The power module of claim 1, wherein the solder repellent structure comprises aluminum.

3. The power module of claim 1, wherein the solder repellent structure comprises a polymer.

4. The power module of claim 1, wherein the solder repellent structure comprises a plurality of separate bond wire loops, and wherein each separate bond wire loop has both a tail end and a ball end attached to the metallic surface of the substrate.

5. The power module of claim 1, wherein the solder repellent structure comprises one or more ribbons or round wires attached to the metallic surface of the substrate by at least two different wedge stitch bonds.

6. The power module of claim 1, wherein the solder repellent structure comprises a plurality of wire wedges attached to the metallic surface of the substrate and laterally spaced apart from one another.

7. The power module of claim 1, wherein the substrate is a direct bonded copper (DBC) substrate, and wherein the metallic surface of the substrate is a metalized surface of an electrically insulative body of the DBC substrate.

8. The power module of claim 1, wherein the solder repellent structure is in the form of a wire or ribbon structure.

9. The power module of claim 1, wherein the electronic component is a shunt resistor.

10. The power module of claim 9, further comprising:
a semiconductor die attached to the metallic surface of the substrate by a solder joint,
wherein the solder repellent structure is laterally interposed between the semiconductor die and the shunt resistor.

11. The power module of claim 9, wherein the shunt resistor comprises:
a first section spaced apart from the metallic surface of the substrate in a vertical direction that is perpendicular to the metallic surface of the substrate, the first section at least partially spanning a gap between a first part and a second part of the metallic surface of the substrate;
a second section extending from a first end of the first section and attached to the first part of the metallic surface of the substrate by a first solder joint; and
a third section extending from a second end of the first section opposite the first end and attached to the second part of the metallic surface of the substrate by a second solder joint.

12. The power module of claim 11, wherein the first section of the shunt resistor comprises zeranin, and wherein the solder repellent structure is configured to prevent solder wetting of the first section of the shunt resistor.

13. A power module, comprising:
a substrate having a metallic surface;
a semiconductor die attached to the metallic surface of the substrate;
a shunt resistor attached to the metallic surface of the substrate; and
a solder repellent structure adjoining the metallic surface of the substrate and laterally interposed between the semiconductor die and the shunt resistor,
wherein the solder repellent structure is configured to repel molten solder.

14. The power module of claim 13, wherein the shunt resistor comprises:
a first section spaced apart from the metallic surface of the substrate in a vertical direction that is perpendicular to the metallic surface of the substrate, the first section at least partially spanning a gap between a first part and a second part of the metallic surface of the substrate;
a second section extending from a first end of the first section and attached to the first part of the metallic surface of the substrate by a first solder joint; and
a third section extending from a second end of the first section opposite the first end and attached to the second part of the metallic surface of the substrate by a second solder joint.

15. The power module of claim 14, wherein the first section of the shunt resistor comprises zeranin, wherein the semiconductor die is attached to the first part of the metallic surface of the substrate, and wherein the solder repellent structure is configured to prevent solder wetting of the first section of the shunt resistor.

16. The power module of claim 13, wherein the solder repellent structure is in the form of a wire or ribbon structure that comprises aluminum.

17. A power module, comprising:
a substrate having a metallic surface;
a semiconductor die attached to the metallic surface of the substrate by a first solder joint;
a shunt resistor attached to the metallic surface of the substrate; and
a solder wetting structure adjoining the metallic surface of the substrate and laterally interposed between the semiconductor die and the shunt resistor,
wherein excess solder squeezed out from under the semiconductor die adheres to the solder wetting structure.

18. The power module of claim 17, wherein the shunt resistor comprises:
a first section spaced apart from the metallic surface of the substrate in a vertical direction that is perpendicular to the metallic surface of the substrate, the first section at least partially spanning a gap between a first part and a second part of the metallic surface of the substrate;
a second section extending from a first end of the first section and attached to the first part of the metallic surface of the substrate by a second solder joint; and
a third section extending from a second end of the first section opposite the first end and attached to the second part of the metallic surface of the substrate by a third solder joint.

19. The power module of claim 18, wherein the first section of the shunt resistor comprises zeranin, and wherein the semiconductor die is attached to the first part of the metallic surface of the substrate by the first solder joint.

20. The power module of claim 17, wherein the solder repellent structure is in the form of a wire or ribbon structure that comprises aluminum.
